(19) United States
(12) Patent Application Publication
(10) Pub. No.: US 2026/0056235 A1
(43) Pub. Date: Feb. 26, 2026

(54) CONTACT PROBE FOR PROBE HEAD OF PROBE CARD IN APPARATUS FOR TESTING ELECTRONIC DEVICE, PROBE HEAD, PROBE CARD, TESTED DEVICE, AND METHOD OF MANUFACTURING CONTACT PROBE

(71) Applicant: MPI CORPORATION, CHU-PEI CITY (TW)

(72) Inventors: CHIN-YI LIN, CHU-PEI CITY (TW); HSIEN-TA HSU, CHU-PEI CITY (TW); CHE-WEI LIN, CHU-PEI CITY (TW); ZE-AN CHEN, CHU-PEI CITY (TW)

(73) Assignee: MPI CORPORATION, CHU-PEI CITY (TW)

(21) Appl. No.: 19/249,158

(22) Filed: Jun. 25, 2025

Related U.S. Application Data
(60) Provisional application No. 63/673,331, filed on Jul. 19, 2024.

(30) Foreign Application Priority Data
Apr. 8, 2025 (TW) 114113241

(51) Int. Cl. G01R 1/073; G01R 31/28

(52) U.S. Cl. CPC G01R 1/07371; G01R 1/07342; G01R 1/07357; G01R 31/2818

(57) ABSTRACT

A contact probe defined with widths and thicknesses along first and second horizontal axes respectively and cross-sectional areas perpendicularly to a vertical axis includes a body portion for being curved at least along the first horizontal axis while disposed between upper and lower die units, a probe tip for contacting a contact pad of a device under test, and a probe tail including a contact end portion with a contact end surface for contacting a contact pad of an interface board. The contact end portion is at least partially smaller in width and thickness than the body portion, so that the contact end surface has an area smaller than a cross-sectional area of the body portion, thereby capable of stable contact with the contact pad of the interface board and prevented from exceeding its edge, obtaining stable contact resistance to ensure test results with stable and high accuracy.

### BACKGROUND OF THE INVENTION

### 1. Field of the Invention

The present invention relates generally to probes for probe cards used in apparatus for testing electronic devices and more particularly, to a contact probe, a probe head and a probe card, which include the contact probe, a tested device that has been tested by the probe card, and a method of manufacturing the contact probe.

### 2. Description of the Related Art

With the trend toward miniaturization of electronic components, contact pads of electronic components are also becoming smaller. The smaller the contact pad, the smaller the contact force it can bear. Therefore, probe cards for testing electronic components with tiny contact pads need to use contact probes with low contact force (or low probe pressure) to avoid applying excessive contact force when the contact probes contact the contact pads of the device under test and damaging the device under test.

In addition to contacting the contact pad of the device under test with its probe tip, the contact probe also needs to contact a contact pad of an interface board (e.g. a space transformer) with its probe tail so that the contact probe and the interface board are electrically connected with each other. However, when contact probes with relatively lower contact force are used, the force applied by the end of the probe tail of the contact probe to the contact pad of the interface board is also relatively lower, which is prone to the problem of unstable contact resistance. That is, unstable contact is formed between the probe tail of the contact probe and the contact pad of the interface board, which will have an unfavorable impact on the accuracy of the test results.

Besides, with the trend toward miniaturization of electronic components, the pitch between the contact pads of the electronic component is also becoming smaller, so the probe cards for testing them requires the characteristic of fine pitch between the contact probes. For example, the pitch between the contact probes is 50-80 micrometers, or even smaller than 50 micrometers. The contact pads of the interface board of the probe card are also reduced in size and pitch accordingly. In such condition, the end of the probe tail of the contact probe is liable to exceed the edge of the contact pad it contacts, so that there may be a risk of insufficient contact area or the contact probe contacting a non-corresponding contact pad.

### SUMMARY OF THE INVENTION

The present invention has been accomplished in view of the above-noted circumstances. It is an objective of the present invention to provide a contact probe for a probe head of a probe card in an apparatus for testing an electronic device, wherein the contact probe has a probe tail with an end capable of stable contact with the contact pad of the interface board to obtain stable contact resistance, enabling the test results to have stable and high accuracy, and the end of the probe tail can be more precisely aligned with the corresponding contact pad, thereby lowering the risk of exceeding the edge of the contact pad.

To attain the above objective, the present invention provides a contact probe. The contact probe is defined with a vertical axis, a first horizontal axis and a second horizontal axis, which are perpendicular to each other. The widths of the contact probe are defined along the first horizontal axis. The thicknesses of the contact probe are defined along the second horizontal axis. The cross-sectional areas of the contact probe are defined perpendicularly to the vertical axis. The contact probe includes a body portion configured in an elongated shape along the vertical axis, a probe tip connected with the body portion and extending downwardly from the body portion along the vertical axis, and a probe tail connected with the body portion and extending upwardly from the body portion along the vertical axis. The body portion is defined with a first central axis extending along the vertical axis. The body portion is adapted to be disposed between an upper die unit and a lower die unit in a way that the body portion is curved at least along the first horizontal axis. The probe tip is adapted to contact a contact pad of a device under test located below the lower die unit. The probe tail includes a contact end portion. The contact end portion includes a contact end surface for mechanically and electrically contacting a contact pad of an interface board. The contact end surface is defined with a second central axis extending along the vertical axis. The contact end portion is at least partially smaller in both width and thickness than the body portion so that the area of the contact end surface is smaller than a cross-sectional area of the body portion.

As a result, compared to the body portion, the contact end portion of the probe tail is reduced in both width and thickness, so as to reduce the area of the contact end surface. That can enhance the stability of the contact between the contact end surface of the probe tail and the contact pad of the interface board, so as to obtain stable contact resistance, enabling the test results to have stable and high accuracy. Besides, the contact end surface of the probe tail, due to its small area, can be more precisely aligned with the corresponding contact pad of the interface board, and can have a sufficient safety distance from the edge of the contact pad that the contact end surface of the probe tail contacts, thereby lowering the risk of the contact end surface of the probe tail exceeding the edge of the contact pad it contacts.

Preferably, the contact end portion of the probe tail of the contact probe at least partially decreases in cross-sectional area gradually along the vertical axis toward the contact end surface.

In other words, the contact end portion of the probe tail is provided with the feature of gradually decreasing in cross-sectional area by being at least partially formed with a slope, tapered surface, or the like, which is inclined relative to the vertical axis. In this way, the contact end portion is prevented from the problem of insufficient structural strength due to the decrease in cross-sectional area.

Preferably, the probe tail includes four lateral surfaces. At least one of the four lateral surfaces includes an inward offset plane. The inward offset plane and a lateral surface of the body portion are parallel to each other, and face toward the same direction. The inward offset plane is offset from the aforementioned lateral surface of the body portion toward the direction opposite to the aforementioned same direction.

In other words, the feature of the probe tail that the contact end surface has the relatively smaller area is not limited to being achieved by the contact end portion being at least partially tapered in shape. This feature may be achieved by the lateral surface of the probe tail being at least partially directly indented with respect to the body portion in a planar (non-tapered) manner such that the probe tail is reduced in cross-sectional area with respect to the body portion in a non-gradually decreasing manner. That can lower the contact force applied by the probe tail to the contact pad of the interface board to a certain extent, and can also reduce the area of the contact end surface to increase the contact resistance and contact stability. The probe tail may even have both the feature for gradually decreasing the cross-sectional area (i.e. the aforementioned slope, tapered surface, or the like), and the feature for non-gradually decreasing the cross-sectional area (i.e. the aforementioned inward offset plane), so as to provide the contact end surface with an appropriate area and generate appropriate contact force and contact resistance to meet the testing requirements.

More preferably, two of the lateral surfaces of the probe tail each includes one aforementioned inward offset plane. The inward offset planes of the two lateral surfaces face toward the positive direction and the negative direction of the first horizontal axis respectively.

After the contact probe is inserted into the upper and lower guiding holes of the upper and lower die units, the upper and lower die units will be displaced relative to each other at least along the first horizontal axis to make the part of the body portion between the upper and lower die units elastically deformed in a curved manner at least along the first horizontal axis. The aforementioned term ‘at least along the first horizontal axis’ means that the upper and lower die units may be displaced relative to each other along both the first and second horizontal axes to make the body portion elastically deformed in a curved manner along the first and second horizontal axes. At this time, the lateral surface of the body portion facing toward the positive direction or negative direction of the first horizontal axis is abutted against the inner surface of the upper guiding hole. That means the part of the body portion located in the upper guiding hole is not centrally aligned with the upper guiding hole, but eccentric with respect to the upper guiding hole at least along the first horizontal axis. By the feature that the probe tail has the inward offset plane facing toward the positive and negative directions of the first horizontal axis, the contact end surface of the probe tail can be adjusted to be less eccentric with respect to the upper guiding hole along the first horizontal axis than the body portion is, or can be even adjusted to be centrally aligned with the upper guiding hole. As a result, the contact end surface of the probe tail can be even more precisely aligned with the corresponding contact pad of the interface board, and can further lower the risk of the contact end surface of the probe tail exceeding the edge of the contact pad it contacts.

Preferably, the probe tail further includes a stop portion and a base portion. The stop portion is connected with the body portion. The base portion is connected between the stop portion and the contact end portion. The cross-sectional area of the stop portion is larger than the cross-sectional area of the body portion so that the probe tail is limited above the upper die unit. The cross-sectional area of the base portion is smaller than the cross-sectional area of the stop portion. The cross-sectional area of the contact end portion is smaller than or equal to the cross-sectional area of the base portion.

As a result, providing the base portion between the contact end portion and the stop portion can enhance the structural strength of the probe tail, making the contact end portion less likely to break when applied with a force. Besides, when the contact probe is inserted into the upper and lower die units, the contact probe is inserted through the upper and lower guiding holes of the upper and lower die units from top to bottom. When the installer looks from top to bottom, it is usually difficult to determine whether the installation direction of the contact probe is correct according to the relative positional relationship between the contact end portion and the stop portion. However, in the case with the base portion, the contact end portion and the base portion can be provided with an obviously identifiable relative positional relationship to improve the efficiency and correctness of installing the contact probe.

More preferably, the base portion has a top surface. The contact end portion is connected with a part of the top surface and located off-center toward at least one side of the base portion, so that the juncture of the contact end portion and the base portion is offset from at least one edge of the top surface of the base portion for a distance along at least one of the first horizontal axis and the second horizontal axis.

As a result, the contact end portion is located off-center toward one side of the base portion along the first horizontal axis, and/or located off-center toward another side of the base portion along the second horizontal axis. In this way, the contact end portion and the base portion is provided with an obviously identifiable relative positional relationship, that can improve the efficiency and correctness of installing the contact probe.

More preferably, the base portion is trapezoid-shaped on a cross-section parallel to the vertical axis.

As a result, the base portion may be trapezoid-shaped on the cross-section defined along the vertical axis and the first horizontal axis, or may be trapezoid-shaped on the cross-section defined along the vertical axis and the second horizontal axis. In this way, the cross-sectional area starts to upwardly gradually decrease from the base portion, thereby ensuring the overall structural strength of the probe tail while providing the contact end surface with the required small area.

More preferably, the width of the base portion is smaller than the width of the stop portion. The thickness of the base portion is smaller than or equal to the thickness of the stop portion, and larger than or equal to the thickness of the contact end portion.

As a result, the base portion only needs to be smaller in width than the stop portion, while the thickness of the base portion may be equal to that of the stop portion, or the thickness of the base portion may be smaller than the thickness of the stop portion, so as to start reducing the cross-sectional area from the base portion to provide the contact end surface with the even smaller area.

More preferably, the base portion and the stop portion are not smoothly connected with each other.

As a result, the base portion and the stop portion are visibly distinguished in their external shapes, instead of jointly forming a smooth, continuous shape. This allows the cross-sectional area of the base portion to have an obvious reduce when compared to the cross-sectional area of the stop portion, so as to start reducing the cross-sectional area from the base portion to provide the contact end surface with the even smaller area. Preferably, the second central axis of the contact end surface of the probe tail is offset from the first central axis of the body portion for a distance along the first horizontal axis.

As described above, when the upper and lower die units are displaced relative to each other along the first horizontal axis to cause the body portion of the contact probe to curve along the first horizontal axis, the part of the body portion located in the upper guiding hole is eccentric with respect to the upper guiding hole along the first horizontal axis. The feature that the second central axis is offset from the first central axis along the first horizontal axis for a distance can make the contact end surface of the probe tail less eccentric with respect to the upper guiding hole along the first horizontal axis than the body portion is, or can even make the contact end surface of the probe tail centrally aligned with the upper guiding hole. As a result, the contact end surface of the probe tail can be even more precisely aligned with the corresponding contact pad of the interface board, and the risk of the contact end surface of the probe tail exceeding the edge of the contact pad it contacts can be further lowered.

More preferably, the second central axis of the contact end surface of the probe tail is further offset from the first central axis of the body portion for another distance along the second horizontal axis.

Since the upper and lower die units may be not only displaced relative to each other along the first horizontal axis but also displaced relative to each other along the second horizontal axis, the part of the body portion located in the upper guiding hole may be also eccentric with respect to the upper guiding hole along the second horizontal axis. The feature that the second central axis is offset from the first central axis for another distance along the second horizontal axis can make the contact end surface of the probe tail less eccentric with respect to the upper guiding hole along the second horizontal axis than the body portion is, or can even make the contact end surface of the probe tail centrally aligned with the upper guiding hole. As a result, the contact end surface of the probe tail can be even more precisely aligned with the corresponding contact pad of the interface board, and the risk of the contact end surface of the probe tail exceeding the edge of the contact pad it contacts can be further lowered.

Preferably, the body portion includes at least one slot extending along the vertical axis. The slot penetrates through the body portion along the second horizontal axis so that the body portion is defined with at least two arms by the at least one slot. The at least two arms are separated from each other along the first horizontal axis.

As a result, the slot can reduce the rigidity of the body portion and thereby lower the contact force applied by the contact probe to the contact pad of the device under test and the contact pad of the interface board, so as to avoid damage to the contact pads caused by excessive contact force. In particular, for high-frequency and high-speed testing requirements, shorter contact probes are usually used to achieve good electrical transmission properties. However, shorter contact probes tend to have higher rigidity and contact force. In such case, the slot can be provided to reduce the contact force of the contact probe. In addition, the slot also increases the elasticity of the body portion, ensuring the elastically curved deformation effect of the body portion along the first horizontal axis.

More preferably, the thickness of the body portion is larger than or equal to the width of the body portion.

Since the body portion is curved along the axis defining the width, i.e. the first horizontal axis, making the width of the body portion not larger than its thickness, or even smaller than its thickness allows the body portion to exhibit better elastic deformation effect, and provides the body portion with a sufficient thickness to reduce the likelihood of breakage.

More preferably, the slot is provided therein with at least one protrusion pair. The protrusion pair includes two protrusions. The two protrusions protrude from two adjacent arms and face each other.

As a result, when the probe tip of the contact probe contacts the contact pad of the device under test and is thereby subjected to a reactive force, the body portion will be compressed, thereby elastically deformed and deflected. At this time, the two protrusions in the slot that face each other will contact each other, that can prevent the adjacent arms from contacting and wearing each other, thereby improving the service life of the contact probe. Furthermore, the contact between the two protrusions facing each other helps to maintain consistent deflection direction and a certain interval between the arms, which is beneficial to the electrical performance in high-frequency and high-speed testing.

The present invention further provides a probe head of a probe card of an apparatus for testing an electronic device. The probe head includes an upper die unit, a lower die unit, and a plurality of probes. The upper die unit includes a plurality of upper guiding holes. The lower die unit includes a plurality of lower guiding holes. The probes are inserted through the upper guiding holes respectively, and inserted through the lower guiding holes respectively. The plurality of probes include at least one above-describe contact probe. The plurality of probes are all curved along the first horizontal axis. Each upper guiding hole is defined with a third central axis. The second central axis of the contact probe is closer, than the first central axis thereof, to the third central axis of the upper guiding hole, through which the contact probe is inserted.

As a result, the contact probe of the probe head of the present invention, due to the small contact end surface of the probe tail thereof, can stably contact the contact pad of the interface board, enabling the test results to have stable and high accuracy. Besides, compared to the body portion, the contact end surface of the probe tail is less eccentric with respect to the upper guiding hole, so that the contact end surface of the probe tail can be more precisely aligned with the corresponding contact pad of the interface board, and can be further ensured with a sufficient safety distance from the edge of the contact pad the contact end surface of the probe tail contacts, thereby further lowering the risk of the contact end surface of the probe tail exceeding the edge of the contact pad it contacts.

Preferably, the second central axis of the contact probe coincides with the third central axis of the upper guiding hole.

As a result, the contact end surface of the probe tail is centrally aligned with the upper guiding hole, so that the contact end surface of the probe tail can be even more precisely aligned with the corresponding contact pad of the interface board, and the risk of the contact end surface of the probe tail exceeding the edge of the contact pad it contacts can be further lowered.

Preferably, the first horizontal axis is defined with two directions opposite to each other. The body portion of the contact probe includes a first abutting surface facing toward one of the directions of the first horizontal axis. The first abutting surface is abutted against an inner surface of the upper guiding hole. The contact end portion of the probe tail of the contact probe is at least partially offset from the first abutting surface toward the other direction of the first horizontal axis.

For example, in the case that the first abutting surface of the body portion faces toward the negative direction of the first horizontal axis, the contact end portion of the probe tail is at least partially offset from the first abutting surface toward the positive direction of the first horizontal axis. As a result, the contact end surface of the probe tail is less eccentric with respect to the upper guiding hole along the first horizontal axis than the body portion is, or may be even centrally aligned with the upper guiding hole. This allows the contact end surface of the probe tail to be more precisely aligned with the corresponding contact pad of the interface board, and further lowers the risk of the contact end surface of the probe tail exceeding the edge of the contact pad it contacts.

Preferably, the second horizontal axis is defined with two directions opposite to each other. The body portion of the contact probe includes a second abutting surface facing toward one of the directions of the second horizontal axis. The second abutting surface is abutted against another inner surface of the upper guiding hole. The contact end portion of the probe tail of the contact probe is at least partially offset from the second abutting surface toward the other direction of the second horizontal axis.

For example, in the case that the second abutting surface of the body portion faces toward the negative direction of the second horizontal axis, the contact end portion of the probe tail is at least partially offset from the second abutting surface toward the positive direction of the second horizontal axis. As a result, the contact end surface of the probe tail is less eccentric with respect to the upper guiding hole along the second horizontal axis than the body portion is, or may be even centrally aligned with the upper guiding hole. This allows the contact end surface of the probe tail to be more precisely aligned with the corresponding contact pad of the interface board, and further lowers the risk of the contact end surface of the probe tail exceeding the edge of the contact pad it contacts.

The present invention further provides a probe card of an apparatus for testing an electronic device. The probe card includes an above-described probe head, and an interface board. The interface board includes a lower surface facing toward the probe head, and a plurality of contact pads located on the lower surface. The contact end surface of the probe tail of the contact probe of the probe head mechanically and electrically contacts the contact pad of the interface board.

As a result, the probe card of the present invention uses the above-described probe head, thereby having its advantages and effects, enabling the test results to have stable and high accuracy, and avoiding the risk of the contact end surface of the probe tail exceeding the edge of the contact pad it contacts.

The present invention further provides a tested device. The tested device is a device that has been tested through a testing process. The device includes a plurality of contact pads. The testing process is performed by using the probes of the above-described probe card to mechanically and electrically contact the contact pads of the device.

As a result, the tested device has been tested with the probe card having the above-described advantages and effects, so the test results thereof have stable and high accuracy, which can ensure the tested device with good performance.

The present invention further provides a method of manufacturing the above-described contact probe, which is characterized in that: the contact probe is made of a base material; the base material is made of an electrically conductive material, and then a top surface of the base material is processed in a laser processing manner (such as laser ablation) so that the base material includes a relatively thicker region that has not been processed in the laser processing manner, and a relatively thinner region that has been reduced in thickness by laser processing; the body portion of the contact probe is derived from the relatively thicker region; the contact end portion of the probe tail of the contact probe is derived from the relatively thinner region.

As a result, the contact end portion of the probe tail of the contact probe is formed with the thickness smaller than that of the body portion in the laser processing manner, so that the probe tail of the contact probe has the relatively smaller contact end surface. The processing using the laser processing manner can provide the contact end portion of the probe tail high dimensional accuracy, allowing the contact probe to meet the required tolerances and thereby improving the production yield of the probe card.

In an embodiment of the present invention, the method of manufacturing the contact probe includes the steps of:
providing the base material, the base material being a board;
processing the top surface of the base material in the laser processing manner to make the base material include the relatively thicker region and the relatively thinner region; and
performing a cutting process to cut the base material into at least one contact probe in a way that the contact probe is provided with the body portion and the contact end portion smaller in width than the body portion through the cutting process.

As a result, the above-described contact probe provided by the present invention can be manufactured from a board by laser processing (such as laser ablation) and the cutting process. During the manufacturing, the laser processing is performed to the top surface of the board, which realizes the reduce of the thickness of the probe tail of the contact probe produced subsequently by cutting. Besides, the process of cutting the board into the contact probe provides the contact probe with the required width arrangement. This method not only enables the production of the contact probe having the above-described advantages and effects, but also allows multiple contact probes to be cut from the same board which has been processed by laser, so that the manufacturing process is convenient and efficient.

Preferably, the cutting process is performed in a laser processing manner (such as laser cutting). This provides the contact probe with even higher dimensional accuracy, thereby further improving the production yield of the probe card.

In another embodiment of the present invention, the method of manufacturing the contact probe includes the steps of:
providing the base material, the base material being a probe body with an elongated shape, the base material being arranged in width identically to the contact probe; and
processing the top surface of the base material in the laser processing manner to make the base material include the relatively thicker region and the relatively thinner region so that at least a part of the relatively thicker region becomes the body portion of the contact probe, and at least a part of the relatively thinner region becomes the contact end portion of the probe tail of the contact probe.

As a result, the above-described contact probe provided by the present invention can be manufactured from an elongated probe body by laser processing (such as laser ablation). The probe body may be formed by a microelectromechanical systems (MEMS) manufacturing process or other manners, and meanwhile the required lateral profile of the contact probe can be formed, so that the probe body has the desired width arrangement of the contact probe to be produced. Then, the laser processing is performed to the top surface of the probe body to realize the reduce of the thickness of the probe tail. This method can also produce the contact probe having the above-described advantages and effects.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic view of a testing apparatus and devices under test according to a preferred embodiment of the present invention;

FIG. 2 is a schematic sectional view of a part of a probe card of the testing apparatus;

FIG. 3 is a schematic planar view of a contact probe for the probe card;

FIG. 4 is a schematic perspective view of a part of the contact probe;

FIG. 5 is a sectional view taken along the line 5-5 in FIG. 2;

FIG. 6 and FIG. 7 are similar to FIG. 4 and FIG. 5 respectively, but showing a probe tail of a different configuration;

FIG. 8 to FIG. 13 are schematic perspective views of partial contact probes of other different configurations;

FIG. 14 to FIG. 23 are schematic planar views of partial contact probes of other different configurations;

FIG. 24 is a schematic perspective view of a part of a contact probe of another different configuration;

FIG. 25 is a flow chart of a method of manufacturing the contact probe provided by the present invention;

FIG. 26 to FIG. 28 are schematic views showing the process of the method shown in FIG. 25;

FIG. 29 is a flow chart of another method of manufacturing the contact probe provided by the present invention;

FIG. 30 to FIG. 31 are schematic views showing the process of the method shown in FIG. 29;

FIG. 32 is a schematic planar view of a contact probe of another different configuration; and

FIG. 33 is a sectional view taken along the line 33-33 in FIG. 32.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

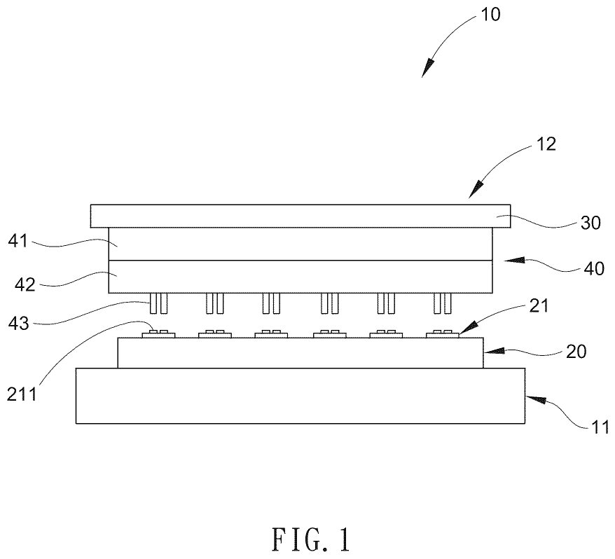

Referring to FIG. 1, an apparatus 10 for testing electronic devices according to a preferred embodiment of the present invention includes a chuck 11 and a probe card 12. The electronic device (also referred to as device under test hereinafter) in this embodiment is formed on a wafer 20. The wafer 20 is placed on the chuck 11. The wafer 20 is formed with multiple devices under test 21. Each device under test 21 includes a plurality of contact pads 211. The probe card 12 at least includes an interface board 30, and a probe head 40. The probe head 40 includes an upper die unit 41, a lower die unit 42, and a plurality of probes 43 inserted in the upper and lower die units 41 and 42. The probe card 12 is adapted to be electrically connected to a tester (not shown), and perform a testing process through the probes 43 mechanically and electrically contacting the contact pads 211 of the devices under test 21.

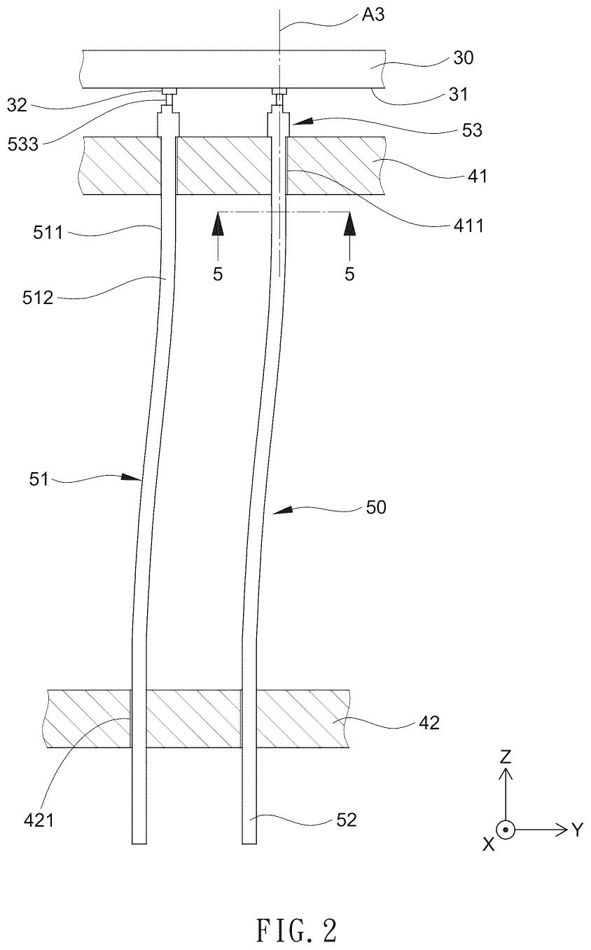

As shown in FIG. 2, the upper die unit 41 includes a plurality of upper guiding holes 411. The lower die unit 42 includes a plurality of lower guiding holes 421. The aforementioned plurality of probes 43 are inserted through the upper guiding holes 411 respectively, and inserted through the lower guiding holes 421 respectively. The probes 43 of the probe head 40 may all or partially be the contact probe 50 as shown in FIG. 2. The contact probe 50 refers to the probe included in the aforementioned probes 43, whose probe tail has some specific structural features, which will be specified hereinafter. The upper and lower die units 41 and 42 in this embodiment each include only one plate. However, the upper die unit 41 and/or lower die unit 42 may be composed of a plurality of plates piled on one another. The upper and lower die units 41 and 42 may be provided at outer rims thereof with protruding structures which are directly connected with each other. Alternatively, there may be a hollow middle die (not shown) connected between the upper and lower die units 41 and 42.

The probe card usually includes a main circuit board adapted to be electrically connected to the tester. The main circuit board may be directly disposed on the probe head, or there may be a space transformer disposed between the main circuit board and the probe head. The interface board 30 mentioned in the present invention refers to a circuit board directly disposed on the probe head 40 and directly contacting the probes 43. Therefore, the interface board 30 may be the aforementioned main circuit board or space transformer. As shown in FIG. 2, the interface board 30 includes a lower surface 31 facing toward the probe head 40, and a plurality of contact pads 32 located on the lower surface 31. The contact probes 50 mechanically and electrically contact the contact pads 32 of the interface board 30 respectively.

During the assembly of the probe head 40, the upper and lower die units 41 and 42 are firstly disposed facing each other, but have not fixed to each other yet. At this time, the upper guiding holes 411 are coaxial with the lower guiding holes 421 respectively. The probe 43 is originally shaped as a straight line, and inserted, from top to bottom, into the upper guiding hole 411 and the lower guiding hole 421 coaxial with each other. After that, the upper and lower die units 41 and 42 are moved relative to each other along a first horizontal axis (Y-axis), so that the upper guiding holes 411 and the lower guiding holes 421 are offset from each other along Y-axis, causing all the probes 43 to be curved along Y-axis. That means the probes 43 have the curved shape as that of the contact probes 50 shown in FIG. 2. The upper and lower die units 41 and 42 may be (but unlimited to) further moved relative to each other along a second horizontal axis (X-axis), so that the upper guiding holes 411 and the lower guiding holes 421 are also offset from each other along X-axis, causing the probes 43 to be also curved along X-axis. After the relative movement is accomplished, the upper and lower die units 41 and 42 are fixed to each other, so that the probes 43 of the probe head 40 are maintained with the curved shape.

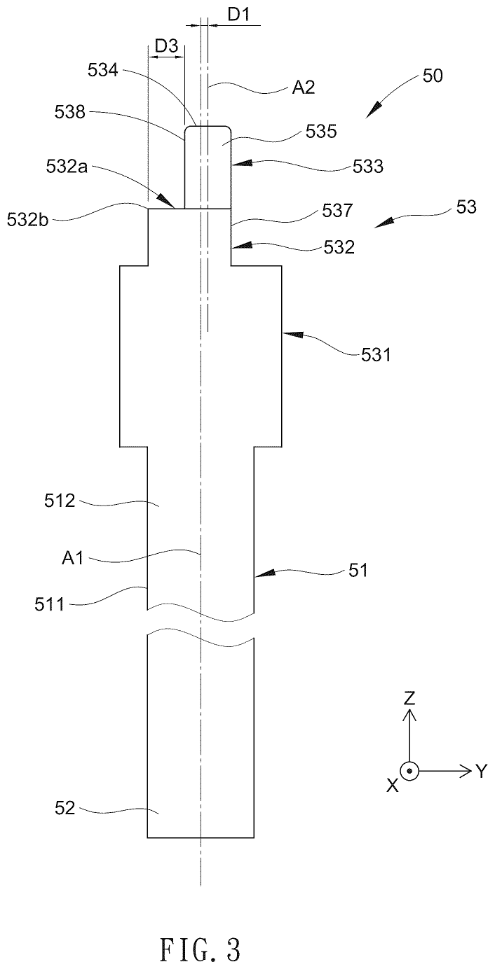

Referring to FIG. 2 and FIG. 3, when the contact probe 50 is still shaped as a straight line, the contact probe 50 includes a body portion 51 configured in an elongated shape along a vertical axis (Z-axis), a probe tip 52 monolithically connected with the body portion 51 and extending downwardly from the body portion 51 along Z-axis, and a probe tail 53 monolithically connected with the body portion 51 and extending upwardly from the body portion 51 along Z-axis. In the present invention, the widths of the contact probe 50 are defined along the first horizontal axis (Y-axis), the thicknesses of the contact probe 50 are defined along the second horizontal axis (X-axis), and the cross-sectional areas of the contact probe 50 are defined perpendicularly to the vertical axis (Z-axis), that is, the cross-sectional areas are defined on X-Y planes. When the assembly of the probe head 40 is accomplished, the probe tail 53 is located above the upper guiding hole 411 for contacting the contact pad 32 of the interface board 30. The probe tip 52 is located below the lower guiding hole 421 for contacting the contact pad 211 of the device under test 21. The body portion 51 is disposed between the upper and lower die units 41 and 42, curved along the first horizontal axis or curved along the first and second horizontal axes, and adapted to be further curved slightly and elastically when the probe tip 52 is pressed on the contact pad 211 of the device under test 21.

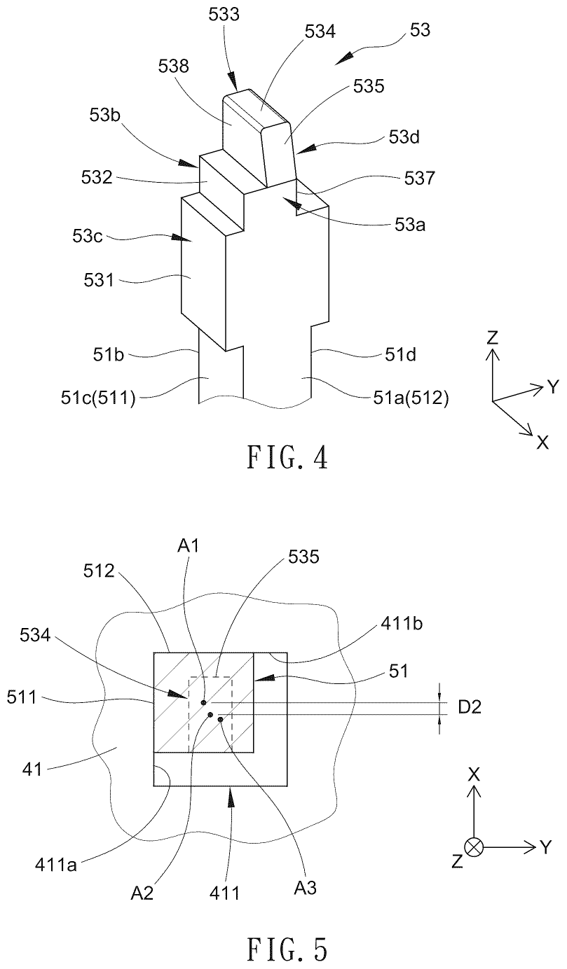

Referring to FIG. 3 and FIG. 4, the probe tail 53 of the contact probe 50 in this embodiment includes, from bottom to top in order, a stop portion 531, a base portion 532, and a contact end portion 533. The stop portion 531 is connected with the body portion 51. The base portion 532 is connected between the stop portion 531 and the contact end portion 533. The stop portion 531 and the body portion 51 are equal in thickness, but the width of the stop portion 531 is larger than the width of the body portion 51. Therefore, the cross-sectional area of the stop portion 531 is larger than the cross-sectional area of the body portion 51. As shown in FIG. 2, the width of the upper guiding hole 411 is a little larger than the width of the body portion 51, but smaller than the width of the stop portion 531. Therefore, the stop portion 531 makes the probe tail 53 limited above the upper die unit 41. The base portion 532 and the stop portion 531 are equal in thickness, or the thickness of the base portion 532 may be smaller than the thickness of the stop portion 531. The width of the base portion 532 is smaller than the width of the stop portion 531. Therefore, the cross-sectional area of the base portion 532 is smaller than the cross-sectional area of the stop portion 531. The width of the contact end portion 533 is smaller than the width of the base portion 532. The thickness of the base portion 532 is larger than or equal to the thickness of the contact end portion 533. The cross-sectional area of the juncture of the contact end portion 533 and the base portion 532 is smaller than the cross-sectional area of the base portion 532, and the cross-sectional area of the contact end portion 533 further gradually decreases upward from the aforementioned juncture. The contact end portion 533 includes a contact end surface 534 located at the topmost end thereof. The contact end surface 534 is adapted to mechanically and electrically contact the contact pad 32 of the interface board 30. The entire contact end portion 533 is smaller in width than the body portion 51. Besides, the entire contact end portion 533, except for the juncture of the contact end portion 533 and the base portion 532, is smaller in thickness than the body portion 51, and the thickness of the contact end portion 533 gradually decreases upward, so that the area of the contact end surface 534 is much smaller than the cross-sectional area of the body portion 51. It should be understandable that the base portion 532 and the stop portion 531 in the present invention are not smoothly connected with each other. That is, the base portion 532 and the stop portion 531 are visibly distinguished in their external shapes, instead of jointly forming a smooth, continuous shape. For example, the base portion 532 and the stop portion 531 are formed with a step shape in the appearance, that is, they have a height difference on their outer surfaces (lateral surfaces).

As a result, compared to the body portion 51, the contact end portion 533 of the probe tail 53 is reduced in both width and thickness, so as to reduce the area of the contact end surface 534. That can enhance the stability of the contact between the contact end surface 534 of the probe tail 53 and the contact pad 32 of the interface board 30, so as to obtain stable contact resistance, enabling the test results to have stable and high accuracy and thereby ensuring the tested device with good performance. Besides, the contact end surface 534 of the probe tail 53, due to its small area, can be more precisely aligned with the corresponding contact pad 32 of the interface board 30, and can have a sufficient safety distance from the edge of the contact pad 32 that the contact end surface 534 of the probe tail 53 contacts, thereby lowering the risk of the contact end surface 534 of the probe tail 53 exceeding the edge of the contact pad 32 it contacts.

Moreover, providing the base portion 532 between the contact end portion 533 and the stop portion 531 can reduce the Z-axial length, or called height, of the contact end portion 533, while reducing the area of the contact end surface 534 of the probe tail 53, so as to enhance the structural strength of the probe tail 53, making the contact end portion 533 less likely to break when applied with a force. Besides, the base portion 532 can be configured with an obviously identifiable relative positional relationship with the contact end portion 533. For example, as shown in FIG. 3, in this embodiment, the right side of the base portion 532 is flush with the right side of the contact end portion 533, but the left side of the base portion 532 significantly protrudes beyond the left side of the contact end portion 533. This left-right asymmetrical configuration design provides an obvious identifiability. When inserting the contact probe 50 through the upper and lower die units 41 and 42 from top to bottom, the installer can easily determine whether the contact probe 50 is correctly oriented during the installation by observing the relative positional relationship between the base portion 532 and the contact end portion 533. This improves the efficiency and correctness of installing the contact probe 50. The base portion 532 and the contact end portion 533 are arranged off-center. Specifically speaking, the contact end portion 533 has a predetermined offset distance with respect to the base portion 532 in the width direction (i.e. the direction in which the probe body is curved), or the contact end portion 533 has a predetermined offset distance with respect to the base portion 532 on Y-axis. More specifically speaking, the base portion 532 has a top surface 532a. The contact end portion 533 is connected and/or formed on a part of the top surface 532a, and located off-center toward at least one side of the base portion 532. In this embodiment, the contact end portion 533 is located off-center toward the right side, and may be also located off-center toward the front side or the rear side. As a result, the juncture of the contact end portion 533 and the base portion 532 is offset from at least one edge 532b of the top surface 532a of the base portion 532 for a distance D3 along at least one of X-axis and Y-axis. In this embodiment, as shown in FIG. 3, the juncture of the contact end portion 533 and the base portion 532 is offset from the left edge of the top surface 532a for the distance D3 along Y-axis, and may be also offset from the front edge or the rear edge of the top surface 532a for another distance along X-axis.

As shown in FIG. 3, the body portion 51 is defined with a first central axis A1 extending along Z-axis. The contact end surface 534 is defined with a second central axis A2 extending along Z-axis. The second central axis A2 is offset from the first central axis A1 along Y-axis for a distance D1. As shown in FIG. 2, each upper guiding hole 411 is defined with a third central axis A3. When the assembly of the probe head 40 is accomplished, the above-described relative movement of the upper and lower die units 41 and 42 along Y-axis makes the first central axis A1 of the body portion 51 offset from the third central axis A3 of the upper guiding hole 411 toward the negative direction of Y-axis, as shown in FIG. 5. Besides, the second central axis A2 of the contact end surface 534 may be further offset from the first central axis A1 of the body portion 51 along X-axis for another distance D2. When the assembly of the probe head 40 is accomplished, the above-described relative movement of the upper and lower die units 41 and 42 along X-axis makes the first central axis A1 of the body portion 51 offset from the third central axis A3 of the upper guiding hole 411 toward the positive direction of X-axis. It should be understandable that when the assembly of the probe head 40 is accomplished, the middle part of the body portion 51 of the contact probe 50 is curved, so the middle part of the first central axis A1 of the body portion 51 is also correspondingly curved. The above-described first central axis A1 being offset from the third central axis A3 of the upper guiding hole 411 refers to the relationship between the part of the first central axis A1 located in the upper guiding hole 411 and the third central axis A3 of the upper guiding hole 411. The configuration design of the contact end portion 533 in this embodiment makes the second central axis A2 of the contact end surface 534 closer to the third central axis A3 of the upper guiding hole 411, through which the contact probe is inserted, than the first central axis A1 of the body portion 51 is, as shown in FIG. 5. The contact end surface 534 is indicated by dotted lines in FIG. 5. In other words, compared to the body portion 51, the contact end surface 534 of the probe tail 53 is less eccentric with respect to the upper guiding hole 411. In this way, the contact end surface 534 of the probe tail 53 can be even more precisely aligned with the corresponding contact pad 32 of the interface board 30, and can further ensure the contact end surface 534 of the probe tail 53 with a sufficient safety distance from the edge of the contact pad 32 it contacts, so as to further lower the risk of the contact end surface 534 of the probe tail 53 exceeding the edge of the contact pad 32 it contacts.

More ideally, the contact end portion 533 may be configured in a way that the second central axis A2 of the contact end surface 534 thereof coincides with the third central axis A3 of the upper guiding hole 411, that is, the contact end surface 534 of the probe tail 53 is centrally aligned with the upper guiding hole 411. In this way, the contact end surface 534 of the probe tail 53 can be even more precisely aligned with the corresponding contact pad 32 of the interface board 30, and the risk of the contact end surface 534 of the probe tail 53 exceeding the edge of the contact pad 32 it contacts can be further lowered.

Further speaking, in the configuration shown in FIG. 2 to FIG. 5, the body portion 51 of the contact probe 50 includes a first abutting surface 511 facing toward the negative direction of Y-axis. The above-described relative movement of the upper and lower die units 41 and 42 along Y-axis makes the first abutting surface 511 of the body portion 51 abutted against an inner surface 411a of the upper guiding hole 411. The contact end portion 533 of the probe tail 53 is offset from the first abutting surface 511 toward the positive direction of Y-axis, that is, as shown in FIG. 3, the Y-axial position of the entire contact end portion 533 is offset to the right from the first abutting surface 511. This configuration design can make the contact end surface 534 of the probe tail 53 less eccentric with respect to the upper guiding hole 411 along Y-axis, or even centrally aligned with the upper guiding hole 411.

On another aspect, the body portion 51 of the contact probe 50 includes a second abutting surface 512 facing toward the positive direction of X-axis. The above-described relative movement of the upper and lower die units 41 and 42 along X-axis makes the second abutting surface 512 abutted against another inner surface 411b of the upper guiding hole 411. The contact end portion 533 of the probe tail 53 is offset from the second abutting surface 512 toward the negative direction of X-axis, that is, as shown in FIG. 4, the X-axial position of a front slope 535 of the contact end portion 533 is gradually, from bottom to top, away from the X-axial position of the second abutting surface 512. This configuration design can make the contact end surface 534 of the probe tail 53 less eccentric with respect to the upper guiding hole 411 along X-axis, or even centrally aligned with the upper guiding hole 411.

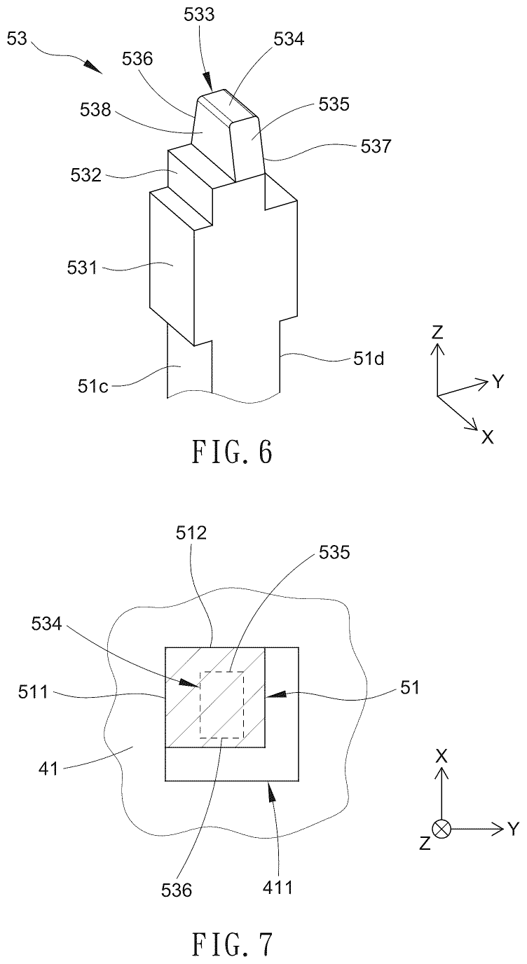

The probe tail 53 of the contact probe 50 may be configured as shown in FIG. 6, which is different from the probe tail 53 shown in FIG. 4 only in that the upwardly gradually decreasing cross-sectional area of the contact end portion 533 in FIG. 4 is only resulted from the front slope 535 provided on the front side of the contact end portion 533, but the upwardly gradually decreasing cross-sectional area of the contact end portion 533 in FIG. 6 is resulted from a front slope 535 and a rear slope 536 provided on the front and rear sides of the contact end portion 533 respectively. That makes the area of the contact end surface 534 even smaller, as shown in FIG. 7. The contact end surface 534 is indicated by dotted lines in FIG. 7. In this way, the contact end surface 534 can be even more precisely aligned with the contact pad 32 of the interface board 30, and the risk of the contact end surface 534 exceeding the edge of the contact pad 32 is further lowered. The contact end portion 533 has the shape of an isosceles trapezoid with a larger bottom and a smaller top. Such geometric structure allows the contact end surface 534 in the upper part to have the small contact area while ensuring sufficient connection strength between the lower part of the contact end portion and the base portion 532, thereby further improving the reliability and performance of the overall design.

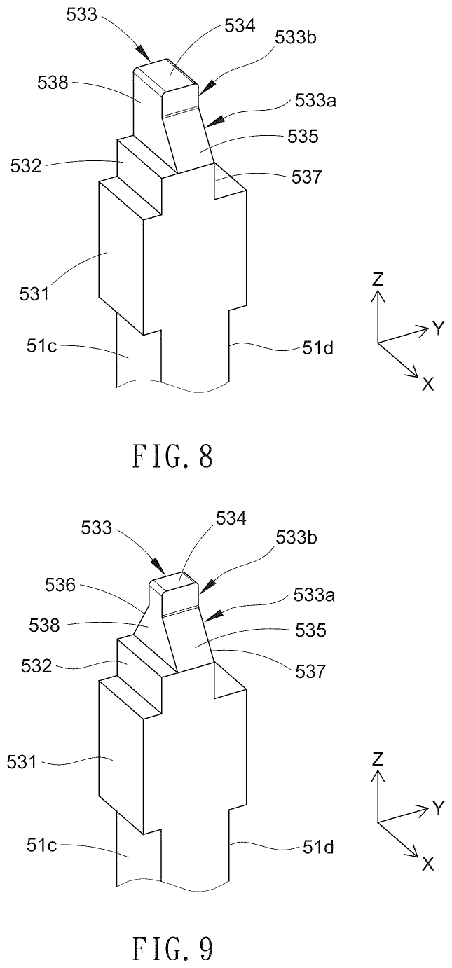

In the configuration shown in FIG. 4 and FIG. 6, the contact end portion 533 of the probe tail 53 is tapered from the lowest end thereof to the contact end surface 534 at the topmost end, so the entire contact end portion 533 gradually decreases in cross-sectional area toward the contact end surface 534 along Z-axis. However, the contact end portion 533 of the probe tail 53 may only partially gradually decrease in cross-sectional area toward the contact end surface 534 along Z-axis. For example, the contact end portion 533 of the probe tail 53 shown in FIG. 8 and FIG. 9 includes a tapered section 533a gradually decreasing in cross-sectional area, and a non-tapered section 533b having a uniform cross-sectional area. By gradually decreasing at least the partial contact end portion 533 of the probe tail 53 in cross-sectional area, rather than abruptly decreasing it, the contact end portion 533 is prevented from the problem of insufficient structural strength due to the reduce in cross-sectional area. In other words, upwardly tapering the contact end portion 533 can make the contact end surface 534 have small area, and further ensure the structural strength of the contact end portion 533. That is, the connecting region between the contact end portion 533 and the base portion 532 can withstand greater pressure or stress, thereby improving the overall structural stability and durability of the contact end portion 533 and reducing the likelihood of damage or deformation caused by uneven stress distribution.

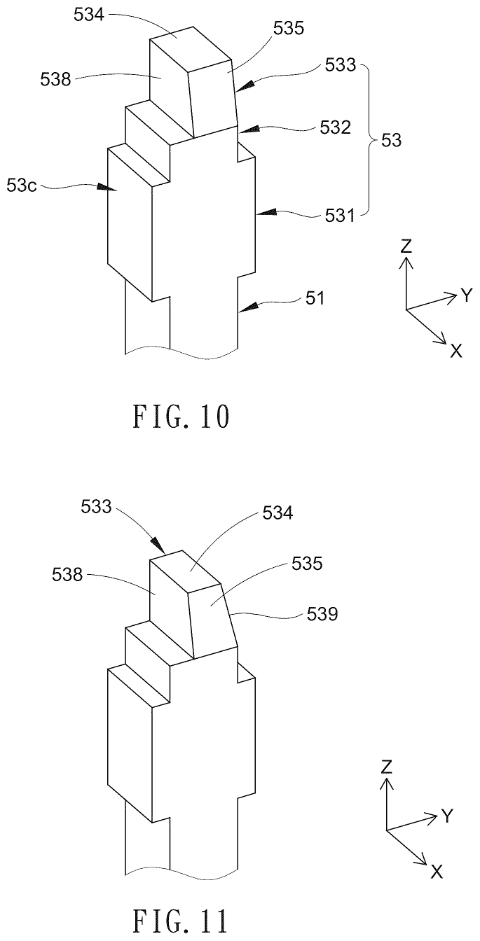

The feature of the probe tail 53 of the contact probe 50 that the contact end surface 534 has the relatively smaller area is not limited to being achieved by the contact end portion 533 being at least partially tapered in shape. This feature can be achieved by at least one lateral surface of the probe tail 53 being at least partially directly indented with respect to the body portion 51 in a planar (non-tapered) manner. Specifically speaking, as shown in FIG. 4, the probe tail 53 includes four lateral surfaces 53a, 53b, 53c and 53d, i.e. front, rear, left and right sides. The body portion 51 also correspondingly has four lateral surfaces 51a, 51b, 51c and 51d. In the configurations shown in FIG. 4, FIG. 6, FIG. 8 and FIG. 9, the lateral surface 53d, i.e. the right side, of the probe tail 53 includes an inward offset plane 537. The inward offset plane 537 and the lateral surface 51d, i.e. the right side, of the body portion 51 are parallel to each other, and face toward the positive direction of Y-axis. The inward offset plane 537 is offset from the lateral surface 51d of the body portion 51 toward the negative direction of Y-axis, i.e. offset to the left. Besides, the lateral surface 53c, i.e. the left side, of the probe tail 53 includes another inward offset plane 538. The inward offset plane 538 and the lateral surface 51, i.e. the left side, of the body portion 51 are parallel to each other, and face toward the negative direction of Y-axis. The inward offset plane 538 is offset from the lateral surface 51c of the body portion 51 toward the positive direction of Y-axis, i.e. offset to the right. In other words, the left and right sides of the probe tail 53 both have their respective inward offset planes 538 and 537, which face toward the negative direction and positive direction of Y-axis respectively. Alternatively, the probe tail 53 may include only one inward offset plane on one of the lateral surfaces, such as the probe tail 53 shown in FIG. 10 and FIG. 11. The probe tail 53 shown in FIG. 10 is different from that shown in FIG. 4 only in that the lateral surface 53c, i.e. the left side, has the inward offset plane 538, but the right side is not indented. Therefore, the base portion 532 and the body portion 51 are equal in width. The probe tail 53 shown in FIG. 11 is different from that shown in FIG. in that the contact end portion 533 further has a right slope 539 making its cross-sectional area upwardly gradually decrease, in addition to the front slope 535.

As a result, the probe tail 53 is reduced in cross-sectional area with respect to the body portion 51 in a non-tapered manner. That can still lower the contact force applied by the probe tail 53 to the contact pad 32 of the interface board 30 to a certain extent, and can also reduce the area of the contact end surface 534 to increase the contact resistance and contact stability. Besides, in each above-described configuration, the probe tail 53 has both the feature for gradually decreasing the cross-sectional area, such as the front slope 535, rear slope 536, right slope 539, and the feature for non-gradually decreasing the cross-sectional area, such as the inward offset plane 537, 538, so as to provide the contact end surface 534 with an appropriate area and generate appropriate contact force and contact resistance to meet the testing requirements. Alternatively, the aforementioned inward offset plane 538 can be replaced by a left slope 540, as shown in FIG. 12, that can achieve the same effects.

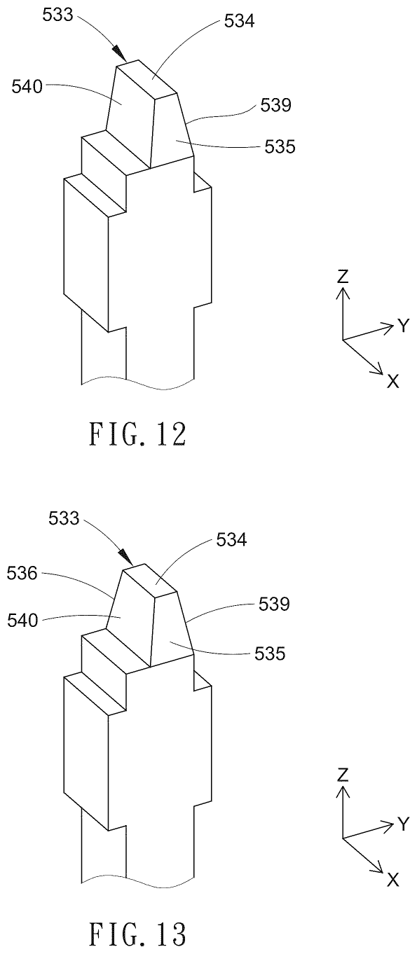

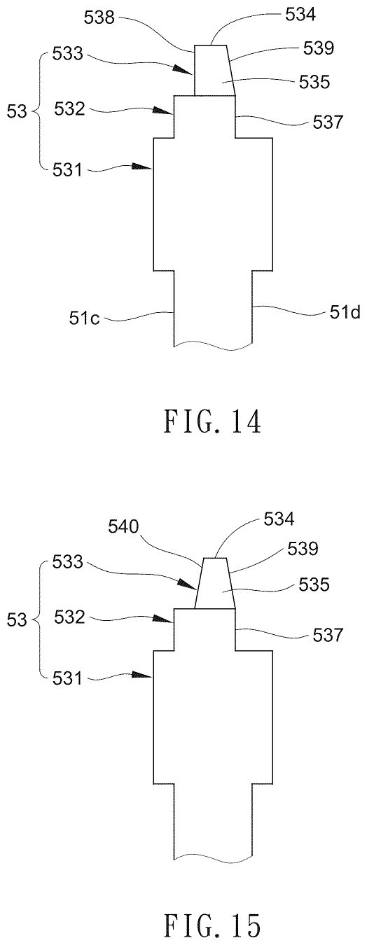

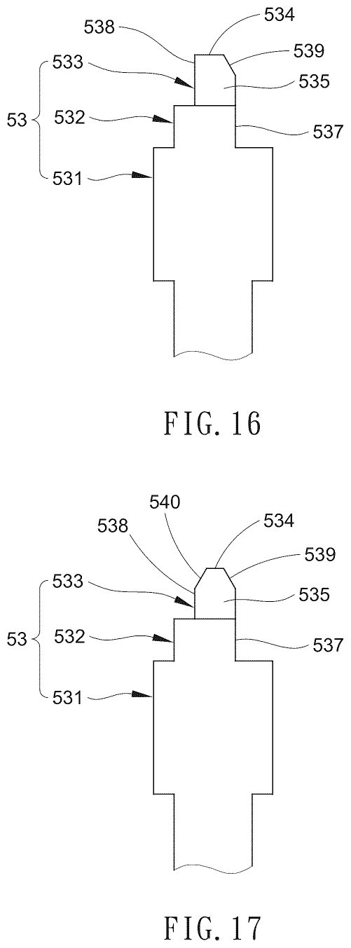

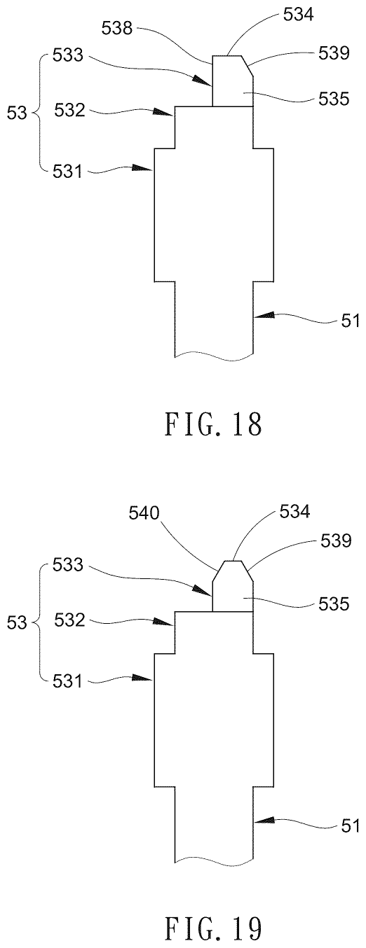

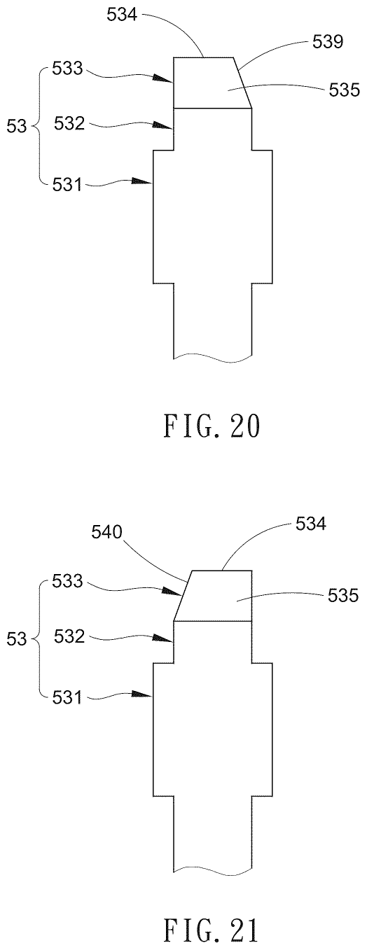

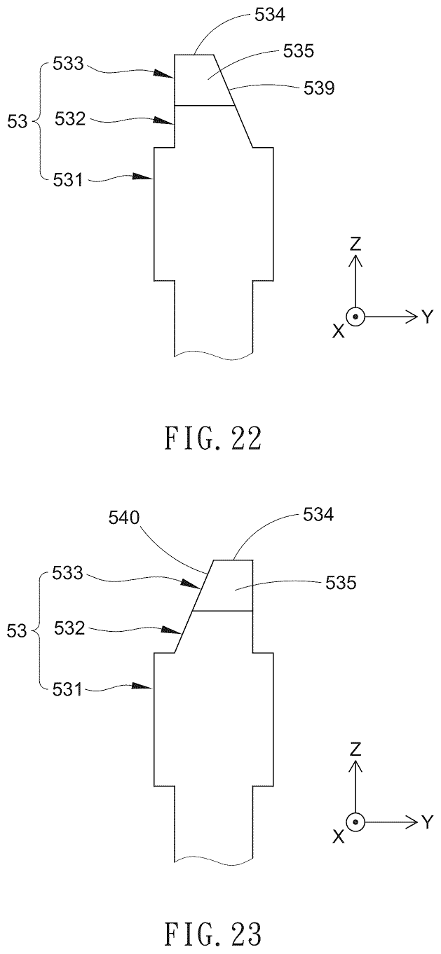

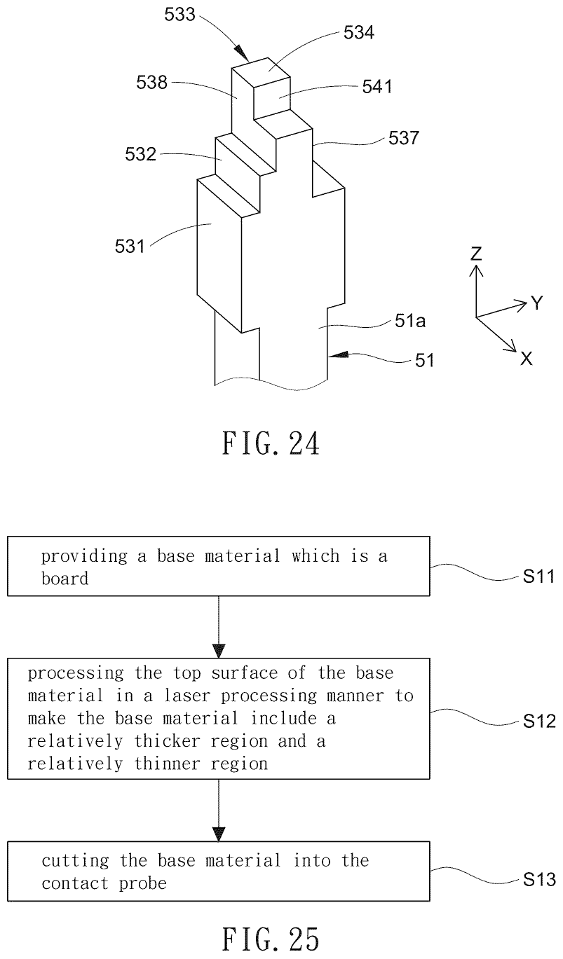

Summarizing the above description, at least anyone of the four lateral surfaces of the probe tail 53 may entirely or partially be an inward offset plane, and/or at least anyone of the four lateral surfaces of the contact end portion 533 of the probe tail 53 may entirely or partially be a slope. That can be arranged according to requirements, such as the following each configuration. The contact end portion 533 of the probe tail 53 shown in FIG. 13 has the front slope 535, the rear slope 536, the right slope 539, and the left slope 540. The probe tail 53 shown in FIG. 14 has the inward offset planes 537, 538, the front slope 535, and the right slope 539. The probe tail 53 shown in FIG. 15 has the inward offset plane 537, the front slope 535, the right slope 539, and the left slope 540. FIG. 16 is similar to FIG. 14, but the right slope 539 is provided on only the partial right side of the contact end portion 533. FIG. 17 is similar to FIG. 15, but the right slope 539 and the left slope 540 are provided on only the partial right side and the partial left side of the contact end portion 533 respectively. FIG. 18 and FIG. 19 are similar to FIG. 16 and FIG. 17 respectively, but the probe tail 53 has no such inward offset plane 537, so that the base portion 532 and the body portion 51 are equal in width. The probe tail 53 shown in FIG. 20 has no inward offset plane. The reduced area of the contact end surface 534 is only resulted from the front slope 535 and the right slope 539. The probe tail 53 shown in FIG. 21 has no inward offset plane. The reduced area of the contact end surface 534 is only resulted from the front slope 535 and the left slope 540. FIG. 22 is similar to FIG. 20, but the right slope 539 is located on both the base portion 532 and the contact end portion 533. FIG. 23 is similar to FIG. 21, but the left slope 540 is located on both the base portion 532 and the contact end portion 533. In FIG. 2 to FIG. 21, the base portion 532 is rectangle-shaped on the vertical cross-sections defined along X-axis and Z-axis and the vertical cross-sections defined along Y-axis and Z-axis, so the front, rear, left and right lateral surfaces of the base portion 532 are all rectangle-shaped. In FIG. 22 and FIG. 23, the base portion 532 is trapezoid-shaped on the vertical cross-sections defined along Y-axis and Z-axis. Alternatively, the base portion 532 may be trapezoid-shaped on the vertical cross-sections defined along X-axis and Z-axis. In other words, the base portion 532 may be trapezoid-shaped on the cross-section parallel to the vertical axis. In this way, the cross-sectional area starts to gradually decrease from the base portion 532 upward, thereby ensuring the overall structural strength of the probe tail 53 while providing the contact end surface 534 with the required small area. Besides, the front slope 535 in each above-described configuration can be replaced by another inward offset plane. For example, the probe tail 53 shown in FIG. 24 is similar to that shown in FIG. 4, but the front side of the contact end portion 533 has no such front slope 535, but has an inward offset plane 541. The inward offset plane 541 and the lateral surface 51a, i.e. the front side, of the body portion 51 are parallel to each other, and face toward the positive direction of X-axis. The inward offset plane 541 is offset from the lateral surface 51a of the body portion 51 toward the negative direction of X-axis.

The present invention further provides a method of manufacturing the contact probe 50, primarily for forming the contact end portion 533 of the probe tail 53, which is reduced in both width and thickness when compared to the body portion 51. Referring to FIG. 25 to FIG. 28, the method will be described by instancing the forming of the probe tail 53 as shown in FIG. 3 and FIG. 4. The method of manufacturing the contact probe 50 includes the following steps S11-S13.

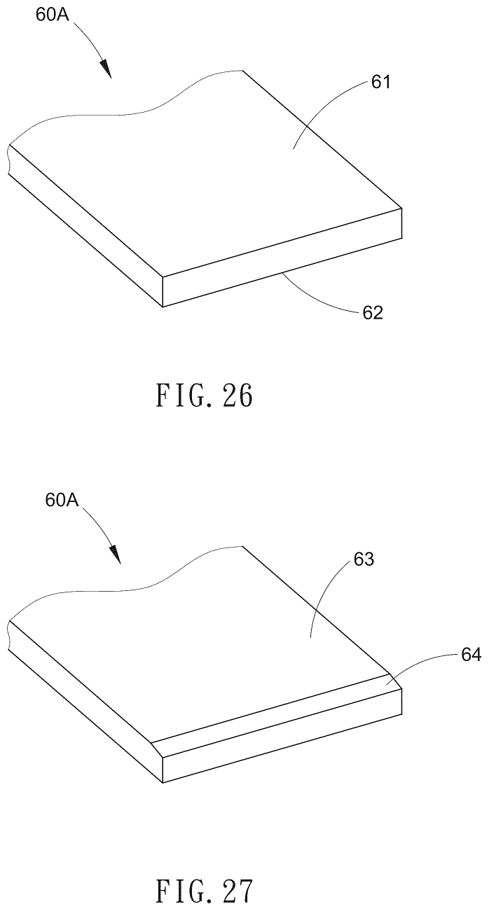

The step S11 is providing a base material 60A, as shown in FIG. 26. The base material 60A is a board made of an electrically conductive material. The base material 60A has a top surface 61, and a bottom surface 62 opposite to the top surface 61. For example, regarding to the selection of the base material 60A, an alloy board or a plated metal board may be used, and an elongated board is used. For example, the board may be formed by a MEMS manufacturing process or by metal hot rolling.

The step S12 is processing the top surface 61 of the base material 60A in a laser processing manner (such as laser ablation) to make the base material 60A include a relatively thicker region 63 that has not been processed in the laser processing manner, and a relatively thinner region 64 that has been reduced in thickness by laser processing, as shown in FIG. 27. For corresponding to the contact end portion 533 of the probe tail 53 shown in FIG. 4, the relatively thinner region 64 in FIG. 27 has an inclined structure gradually decreasing in thickness. The aforementioned laser processing manner (such as laser ablation) refers to the direct application of a laser beam onto the base material 60A, wherein the energy of the laser ablates the base material 60A to reduce the thickness of the base material 60A.

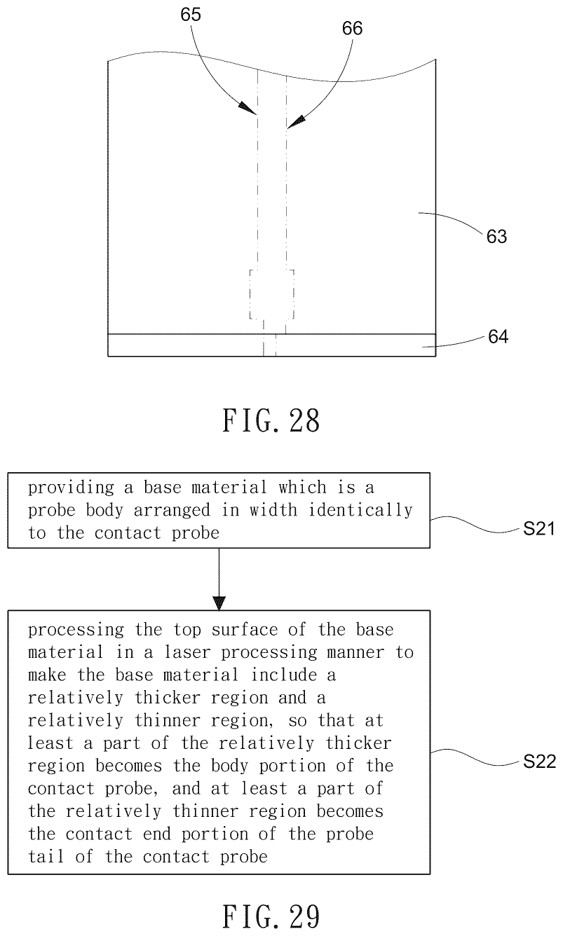

The step S13 is performing a cutting process to cut the base material 60A into at least one contact probe 50. For example, the cutting may be performed along two cutting paths 65 and 66 shown in FIG. 28 to cut out the contact probe 50 as shown in FIG. 3, so that the body portion 51, the stop portion 531 and the base portion 532 of the probe tail 53 of the contact probe 50 come from the relatively thicker region 63 of the base material 60A, and the contact end portion 533 of the probe tail 53 comes from the relatively thinner region 64 of the base material 60A. In this way, the thickness of the contact end portion 533 is smaller than the thickness of the body portion 51. Besides, the lateral surface 51d of the body portion 51 and the lateral surface 53d of the probe tail 53 are formed through the cutting path 65. The lateral surface 51c of the body portion 51 and the lateral surface 53c of the probe tail 53 are formed through the cutting path 66. The contact probe 50 is provided with the required width variation through this cutting process, making the width of the contact end portion 533 smaller than the width of the body portion 51. This cutting process can be performed in a laser processing manner, such as laser cutting.

As a result, the contact end portion 533 of the probe tail 53 of the contact probe 50 is formed with the thickness smaller than that of the body portion 51 in a way that the thickness of the base material is reduced by laser processing, and the contact probe 50 is formed with the required width arrangement in the process that the board is cut into the contact probe 50. Such method of manufacturing the contact probe 50 provides the probe tail 53 thereof with the small-area contact end surface 534, and the resulting advantages and effects of the contact probe 50 as described above. The processing using the laser processing manner can provide the contact end portion 533 of the probe tail 53 high dimensional accuracy, allowing the contact probe 50 to meet the required tolerances and thereby improving the production yield of the probe card 12. Besides, this method allows multiple contact probes 50 to be cut from the same board which has been processed by laser, so that the manufacturing process is convenient and efficient.

Referring to FIG. 29 to FIG. 31, the contact probe 50 of the present invention can be manufactured by another method. The following description instances the forming of the probe tail 53 as shown in FIG. 3 and FIG. 4. The method of manufacturing the contact probe 50 includes the following steps S21-S22.

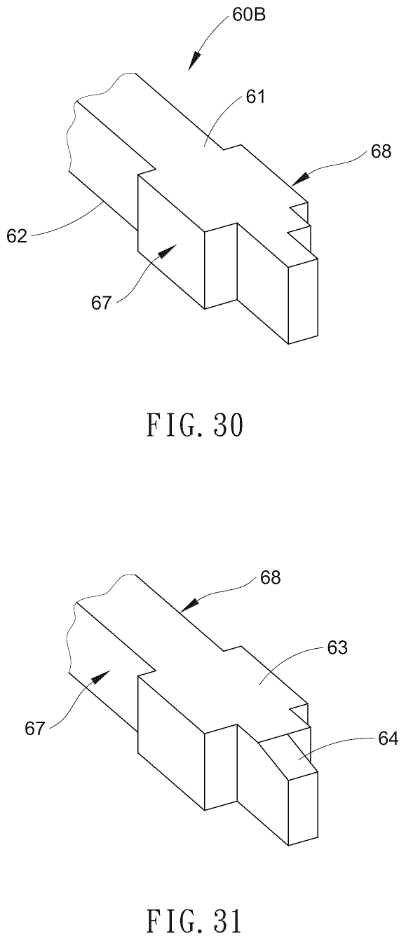

The step S21 is providing a base material 60B, as shown in FIG. 30. The base material 60B is a probe body with an elongated shape, which is made of an electrically conductive material. The base material 60B is arranged in width identically to the contact probe 50. Specifically speaking, the base material 60B has a top surface 61, a bottom surface 62 opposite to the top surface 61, and two opposite lateral surfaces 67, 68. For example, the probe body can be formed by a MEMS manufacturing process, wherein multiple probe bodies are usually formed on a substrate (not shown) at the same time, and the following step is performed to the multiple probe bodies at the same time for manufacturing multiple contact probes 50. There is only one probe body schematically shown in FIG. 30. At this time, the required lateral profile of the contact probe 50 can be formed, so the lateral surface 67 of the base material 60B already includes the lateral surface 51d of the body portion 51 and the lateral surface 53d of the probe tail 53 of the contact probe 50, and the lateral surface 68 already includes the lateral surface 51c of the body portion 51 and the lateral surface 53c of the probe tail 53 of the contact probe 50. In other embodiments, the probe body can be formed in a laser processing manner (such as laser cutting), wherein multiple probe bodies are usually formed on a substrate (not shown) at the same time, and the required lateral profile of the contact probe 50 is formed.

The step S22 is processing the top surface 61 of the base material 60B in a laser processing manner (such as laser ablation) to make the base material 60B include a relatively thicker region 63 that has not been processed in the laser processing manner, and a relatively thinner region 64 that has been reduced in thickness by laser processing, as shown in FIG. 31, so that at least a part of the relatively thicker region 63 becomes the body portion 51 of the contact probe 50, and at least a part of the relatively thinner region 64 becomes the contact end portion 533 of the probe tail 53 of the contact probe 50. For corresponding to the contact end portion 533 of the probe tail 53 shown in FIG. 4, the relatively thinner region 64 in FIG. 31 has an inclined structure gradually decreasing in thickness.

As a result, the contact probe 50 can be manufactured by providing an elongated probe body which already has the desired lateral profile, and then processing it in the laser processing manner to realize the reduce of the thickness of the probe tail 53, thereby forming the contact end portion 533 that is smaller in thickness than the body portion 51. This method can also produce the contact probe 50 having the above-described advantages and effects. The processing using the laser processing manner can provide the contact end portion 533 of the probe tail 53 high dimensional accuracy, allowing the contact probe 50 to meet the required tolerances and thereby improving the production yield of the probe card 12.

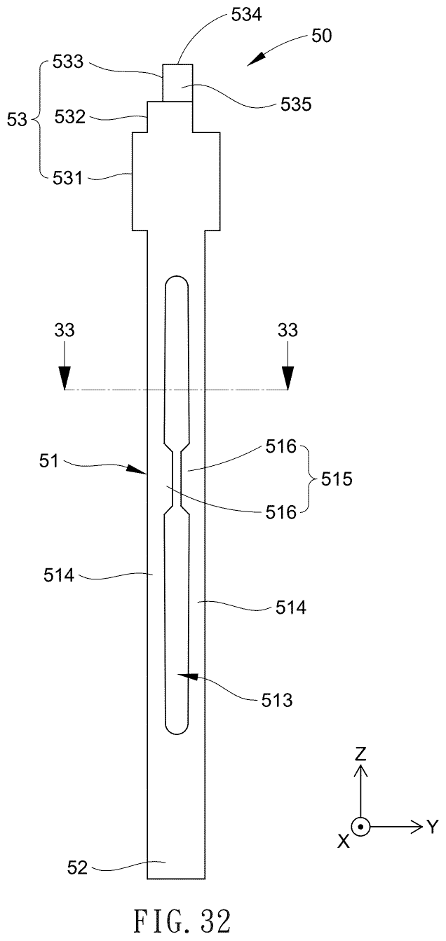

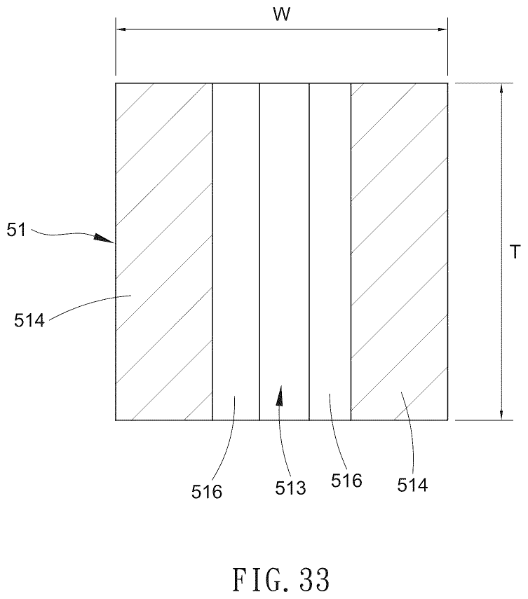

Referring to FIG. 32 and FIG. 33, the body portion 51 of the contact probe 50 of the present invention may include at least one slot 513. The slot 513 extends into an elongated shape in the longitudinal direction of the body portion 51. That is, when the body portion 51 has not been curved, the slot 513 extends along Z-axis. The slot 513 penetrates through the body portion 51 along X-axis so that the body portion 51 is defined with at least two arms 514, which are shaped as thin sheets, by the at least one slot 513. The at least two arms 514 are separated from each other along Y-axis. Such slot 513 can reduce the rigidity of the body portion 51 and thereby lower the contact force applied by the contact probe 50 to the contact pad 211 of the device under test 21 and the contact pad 32 of the interface board 30, so as to avoid damage to the contact pads 211, 32 caused by excessive contact force. In particular, for high-frequency and high-speed testing requirements, shorter contact probes 50 are usually used to achieve good electrical transmission properties. However, shorter contact probes 50 tend to have higher rigidity and contact force. In such case, the slot 513 can be provided to reduce the contact force of the contact probe 50. In addition, the slot 513 also increases the elasticity of the body portion 51, ensuring the elastically curved deformation performance of the body portion 51 along Y-axis. Further speaking, since the body portion 51 is curved along Y-axis, and widths are defined on Y-axis, the body portion 51 can be configured in a way that the thickness T of the body portion 51 is larger than or equal to the width W of the body portion 51, allowing the body portion 51 to exhibit better elastic deformation effect and providing the body portion 51 with sufficient thickness T to reduce the likelihood of breakage.

Furthermore, the slot 513 may be provided therein with at least one protrusion pair 515. The protrusion pair 515 includes two protrusions 516. The two protrusions 516 protrude from two adjacent arms 514 and face each other. As a result, when the probe tip 52 of the contact probe 50 contacts the contact pad 211 of the device under test 21 and is thereby subjected to a reactive force, the body portion 51 will be compressed, thereby elastically deformed and deflected. At this time, the two protrusions 513 in the slot 513 that face each other will contact each other, thereby preventing the adjacent arms 514 from contacting and wearing each other. This improves the service life of the contact probe 50. Besides, the contact between the two protrusions 516 facing each other helps to maintain consistent deflection direction and a certain interval between the arms 514, which is beneficial to the electrical performance in high-frequency and high-speed testing.

The invention being thus described, it will be obvious that the same may be varied in many ways. Such variations are not to be regarded as a departure from the scope of the invention, and all such modifications as would be obvious to one skilled in the art are intended to be included within the scope of the following claims.

What is claimed is:

1. A contact probe for a probe head of a probe card in an apparatus for testing an electronic device, the contact probe being defined with a vertical axis, a first horizontal axis and a second horizontal axis, which are perpendicular to each other, widths of the contact probe being defined along the first horizontal axis, thicknesses of the contact probe being defined along the second horizontal axis, cross-sectional areas of the contact probe being defined perpendicularly to the vertical axis, the contact probe comprising:
a body portion configured in an elongated shape along the vertical axis, the body portion being defined with a first central axis extending along the vertical axis, the body portion being adapted to be disposed between an upper die unit and a lower die unit in a way that the body portion is curved at least along the first horizontal axis;
a probe tip connected with the body portion and extending downwardly from the body portion along the vertical axis for contacting a contact pad of a device under test located below the lower die unit; and
a probe tail connected with the body portion and extending upwardly from the body portion along the vertical axis;
wherein the probe tail comprises a contact end portion; the contact end portion comprises a contact end surface for mechanically and electrically contacting a contact pad of an interface board; the contact end surface is defined with a second central axis extending along the vertical axis; the contact end portion is at least partially smaller in both width and thickness than the body portion so that an area of the contact end surface is smaller than a cross-sectional area of the body portion.

2. The contact probe as claimed in claim 1, wherein the contact end portion of the probe tail at least partially decreases in cross-sectional area gradually along the vertical axis toward the contact end surface.

3. The contact probe as claimed in claim 1, wherein the probe tail comprises four lateral surfaces; at least one of the four lateral surfaces comprises an inward offset plane; the inward offset plane and a lateral surface of the body portion are parallel to each other, and face toward a same direction; the inward offset plane is offset from the lateral surface of the body portion toward a direction opposite to said same direction.

4. The contact probe as claimed in claim 3, wherein two of the lateral surfaces of the probe tail each comprise one said inward offset plane; the two inward offset planes face toward a positive direction and a negative direction of the first horizontal axis respectively.

5. The contact probe as claimed in claim 1, wherein the probe tail further comprises a stop portion and a base portion; the stop portion is connected with the body portion; the base portion is connected between the stop portion and the contact end portion; the cross-sectional area of the stop portion is larger than the cross-sectional area of the body portion so that the probe tail is limited above the upper die unit; the cross-sectional area of the base portion is smaller than the cross-sectional area of the stop portion; the cross-sectional area of the contact end portion is smaller than or equal to the cross-sectional area of the base portion.

6. The contact probe as claimed in claim 5, wherein the base portion has a top surface; the contact end portion is connected with a part of the top surface, and located off-center towards at least one side of the base portion so that a juncture of the contact end portion and the base portion is offset from at least one edge of the top surface of the base portion for a distance along at least one of the first horizontal axis and the second horizontal axis.

7. The contact probe as claimed in claim 5, wherein the base portion is trapezoid-shaped on a cross-section parallel to the vertical axis.

8. The contact probe as claimed in claim 5, wherein the width of the base portion is smaller than the width of the stop portion; the thickness of the base portion is smaller than or equal to the thickness of the stop portion, and larger than or equal to the thickness of the contact end portion.

9. The contact probe as claimed in claim 5, wherein the base portion and the stop portion are not smoothly connected with each other.

10. The contact probe as claimed in claim 1, wherein the second central axis of the contact end surface of the probe tail is offset from the first central axis of the body portion for a distance along the first horizontal axis.

11. The contact probe as claimed in claim 10, wherein the second central axis of the contact end surface of the probe tail is further offset from the first central axis of the body portion for another distance along the second horizontal axis.

12. The contact probe as claimed in claim 1, wherein the body portion comprises at least one slot extending along the vertical axis; the slot penetrates through the body portion along the second horizontal axis so that the body portion is defined with at least two arms by the at least one slot; the at least two arms are separated from each other along the first horizontal axis.

13. The contact probe as claimed in claim 12, wherein the thickness of the body portion is larger than or equal to the width of the body portion.

14. The contact probe as claimed in claim 12, wherein the slot is provided therein with at least one protrusion pair; the protrusion pair comprises two protrusions; the two protrusions protrude from two adjacent said arms, and face each other.

15. A probe head of a probe card of an apparatus for testing an electronic device, the probe head comprising:
an upper die unit comprising a plurality of upper guiding holes;
a lower die unit comprising a plurality of lower guiding holes; and
a plurality of probes inserted through the upper guiding holes respectively and inserted through the lower guiding holes respectively, the plurality of probes comprising at least one contact probe as claimed in claim 1;
wherein the probes are all curved along the first horizontal axis; each of the upper guiding holes is defined with a third central axis; the second central axis of the contact probe is closer to the third central axis of the upper guiding hole, through which the contact probe is inserted, than the first central axis is.

16. The probe head as claimed in claim 15, wherein the second central axis of the contact probe coincides with the third central axis of the upper guiding hole.

17. The probe head as claimed in claim 15, wherein the first horizontal axis is defined with two directions opposite to each other; the body portion of the contact probe comprises a first abutting surface facing toward one of the directions of the first horizontal axis; the first abutting surface is abutted against an inner surface of the upper guiding hole; the contact end portion of the probe tail of the contact probe is at least partially offset from the first abutting surface toward the other direction of the first horizontal axis; the second horizontal axis is defined with two directions opposite to each other; the body portion of the contact probe comprises a second abutting surface facing toward one of the directions of the second horizontal axis; the second abutting surface is abutted against another inner surface of the upper guiding hole; the contact end portion of the probe tail of the contact probe is at least partially offset from the second abutting surface toward the other direction of the second horizontal axis.

18. A probe card of an apparatus for testing an electronic device, the probe card comprising:
the probe head as claimed in claim 15; and
an interface board comprising a lower surface facing toward the probe head, and a plurality of contact pads located on the lower surface;
wherein the contact end surface of the probe tail of the contact probe of the probe head mechanically and electrically contacts the contact pad of the interface board.

19. A tested device, the tested device being a device that has been tested through a testing process, the device comprising a plurality of contact pads, the testing process is performed by using the probes of the probe card as claimed in claim 18 to mechanically and electrically contact the contact pads of the device.

20. A method of manufacturing the contact probe as claimed in claim 1, the method being characterized in that:
the contact probe is made of a base material; the base material is made of an electrically conductive material, and then a top surface of the base material is processed in a laser processing manner so that the base material comprises a relatively thicker region that has not been processed in the laser processing manner, and a relatively thinner region that has been reduced in thickness by laser processing; the body portion of the contact probe is derived from the relatively thicker region; the contact end portion of the probe tail of the contact probe is derived from the relatively thinner region.

21. The method as claimed in claim 20, wherein the method comprises the steps of:
providing the base material, the base material being a board;
processing the top surface of the base material in the laser processing manner to make the base material comprise the relatively thicker region and the relatively thinner region; and
performing a cutting process to cut the base material into at least one said contact probe in a way that the contact probe is provided with the body portion and the contact end portion smaller in width than the body portion through the cutting process.

22. The method as claimed in claim 21, wherein the cutting process is performed in a laser processing manner.

23. The method as claimed in claim 20, wherein the method comprises the steps of:
providing the base material, the base material being a probe body with an elongated shape, the base material being arranged in width identically to the contact probe; and
processing the top surface of the base material in the laser processing manner to make the base material comprise the relatively thicker region and the relatively thinner region, so that at least a part of the relatively thicker region becomes the body portion of the contact probe, and at least a part of the relatively thinner region becomes the contact end portion of the probe tail of the contact probe.

24. A method of manufacturing a contact probe, the method comprising the steps of:
providing a base material made of an electrically conductive material; and
making the base material into at least one contact probe, comprising processing a top surface of the base material in a laser processing manner to make the base material comprise a relatively thicker region that has not been processed in the laser processing manner and a relatively thinner region that has been reduced in thickness by laser processing, defining a body portion of the contact probe in the relatively thicker region, and defining a contact end portion of a probe tail of the contact probe in the relatively thinner region.
